(19) United States
(12) Patent Application Publication
(10) Pub. No.: US 2024/0178095 A1
(43) Pub. Date: May 30, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Wensen Hung, Hsinchu County (TW); Tsung-Yu Chen, Hsinchu City (TW); Meng-Tsan Lee, Hsinchu (TW)

(73) Assignee: Taiwan Semiconductor Manufacturing Company, Ltd., Hsinchu (TW)

(21) Appl. No.: 18/167,081

(22) Filed: Feb. 10, 2023

Related U.S. Application Data
(60) Provisional application No. 63/427,904, filed on Nov. 24, 2022.

(51) Int. Cl. H01L 23/367; H01L 23/00; H01L 23/373; H01L 25/065; H10B 80/00

(52) U.S. Cl. CPC H01L 23/3675; H01L 23/3736; H01L 23/3737; H01L 24/32; H01L 25/0655; H10B 80/00; H01L 24/03; H01L 24/05; H01L 24/11; H01L 24/13; H01L 24/16; H01L 24/33; H01L 24/73; H01L 24/94; H01L 2224/0345; H01L 2224/03622; H01L 2224/0391; H01L 2224/0401; H01L 2224/05022; H01L 2224/05124; H01L 2224/05147; H01L 2224/05558; H01L 2224/05572; H01L 2224/05647; H01L 2224/05666; H01L 2224/05681; H01L 2224/05686; H01L 2224/11462; H01L 2224/11464; H01L 2224/11849; H01L 2224/11912; H01L 2224/13083; H01L 2224/13124; H01L 2224/13147; H01L 2224/13155; H01L 2224/13166; H01L 2224/13184; H01L 2224/16238; H01L 2224/32225; H01L 2224/32245; H01L 2224/33181; H01L 2224/73204; H01L 2224/73253; H01L 2224/94; H01L 2924/04941; H01L 2924/04953; H01L 2924/1431; H01L 2924/1432

(57) ABSTRACT

A semiconductor device includes a substrate, a first device, a second device, a ring structure, a lid structure, and a first adhesive layer. The first device is disposed on the substrate. The second device is adjacent to the first device and is disposed on the substrate. The ring structure is disposed over the substrate and the second device. The ring structure includes a cover and a leg extending out from the cover. The cover has a through opening. The lid structure is disposed over the ring structure and the first device. The lid structure includes a body and a protrusion protruding from the body. The protrusion of the lid structure is inserted into the through opening of the cover of the ring structure. The first adhesive layer is disposed between the body of the lid structure and the cover of the ring structure and includes phase change thermal interface material.

### CROSS-REFERENCE TO RELATED APPLICATION

This application claims the priority benefit of U.S. provisional application Ser. No. 63/427,904, filed on Nov. 24, 2022. The entirety of the above-mentioned patent application is hereby incorporated by reference herein and made a part of this specification.

### BACKGROUND

The semiconductor integrated circuit (IC) industry has experienced rapid growth. Over the course of this growth, functional density of the devices has generally increased by the device feature size. This scaling down process generally provides benefits by increasing production efficiency, lower costs, and/or improving performance. Such scaling down has also increased the complexities of processing and manufacturing IC. For these advances to be realized, developments in IC fabrication are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1H are schematic cross-sectional views illustrating a manufacturing process of a semiconductor die in accordance with some embodiments of the disclosure.

FIG. 2A to FIG. 2C are schematic cross-sectional views illustrating a manufacturing process of a package structure in accordance with some embodiments of the disclosure.

FIG. 3A to FIG. 3C are schematic cross-sectional views illustrating a manufacturing process of a semiconductor device in accordance with some embodiments of the disclosure.

FIG. 4A to FIG. 4C are schematic top views of FIG. 3A to FIG. 3C.

FIG. 5 is a schematic cross-sectional view illustrating a semiconductor device in accordance with some alternative embodiments of the disclosure.

FIG. 6 is a schematic cross-sectional view illustrating a semiconductor device in accordance with some alternative embodiments of the disclosure.

FIG. 7A to FIG. 7C are schematic cross-sectional views illustrating a manufacturing process of a semiconductor device in accordance with some alternative embodiments of the disclosure.

FIG. 8A to FIG. 8C are schematic top views of FIG. 7A to FIG. 7C.

FIG. 9 is a schematic cross-sectional view illustrating a semiconductor device in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

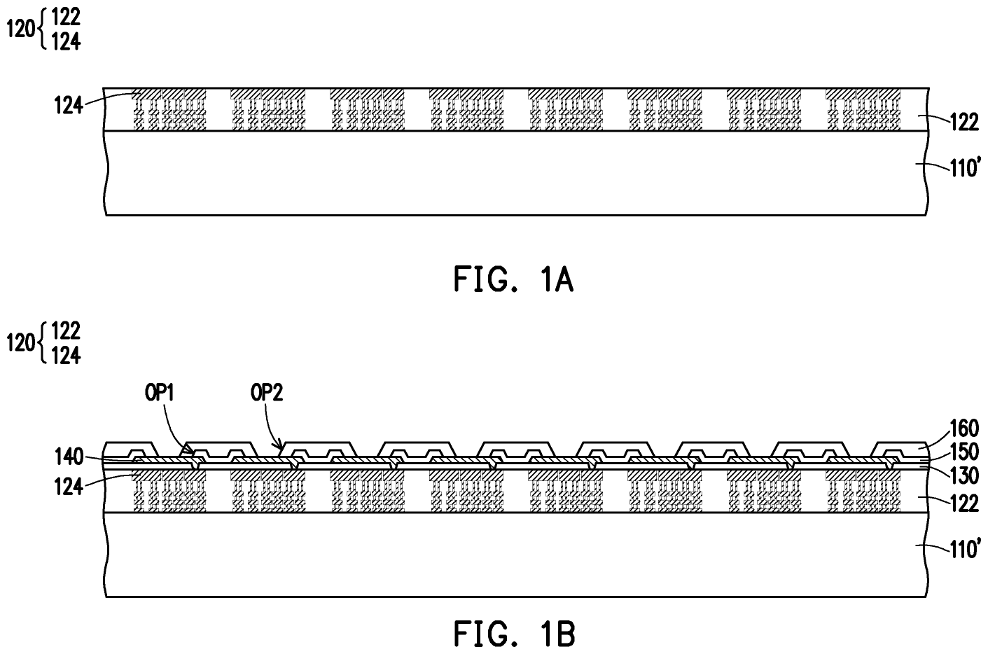

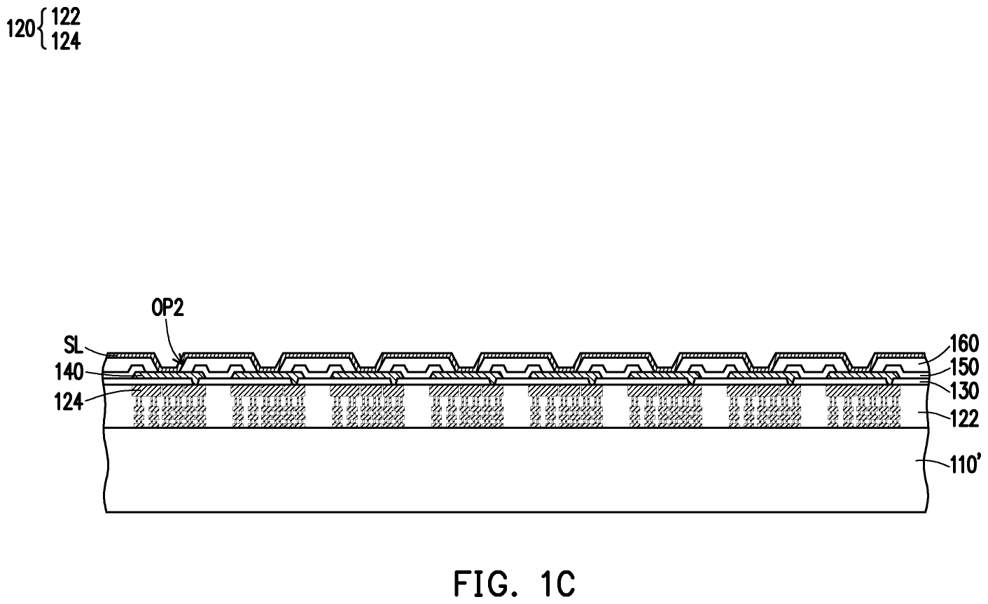

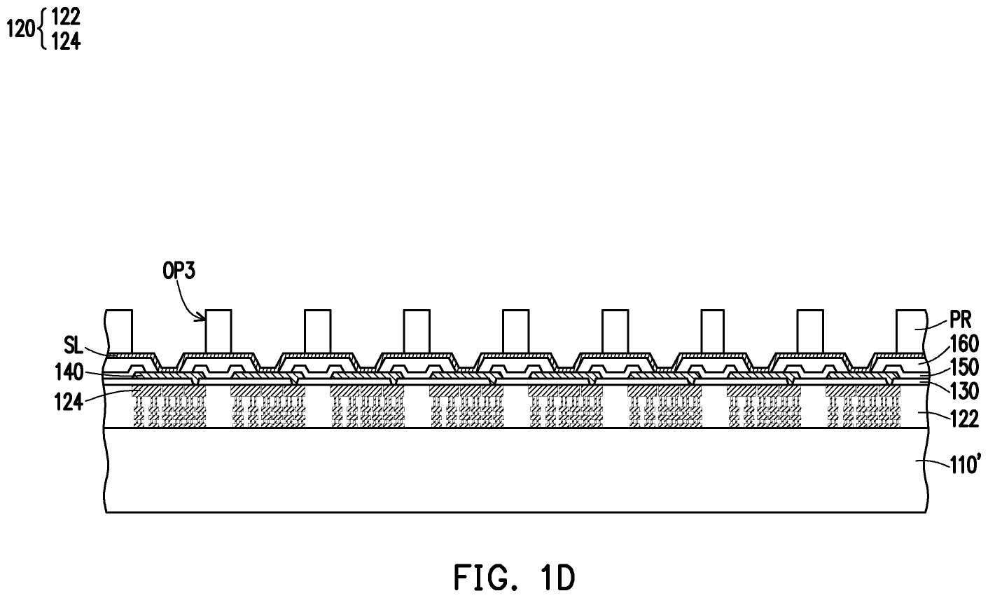

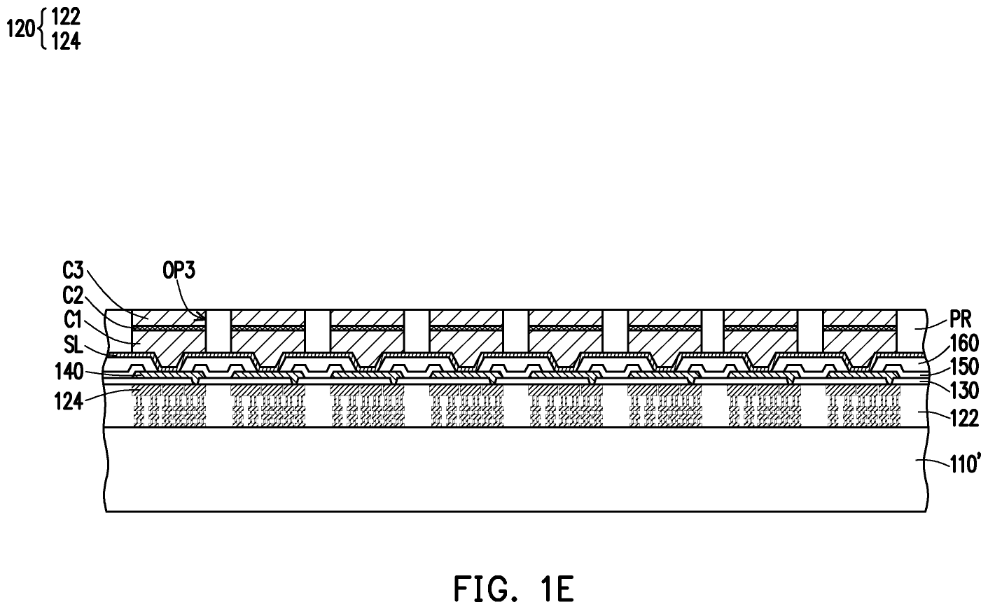

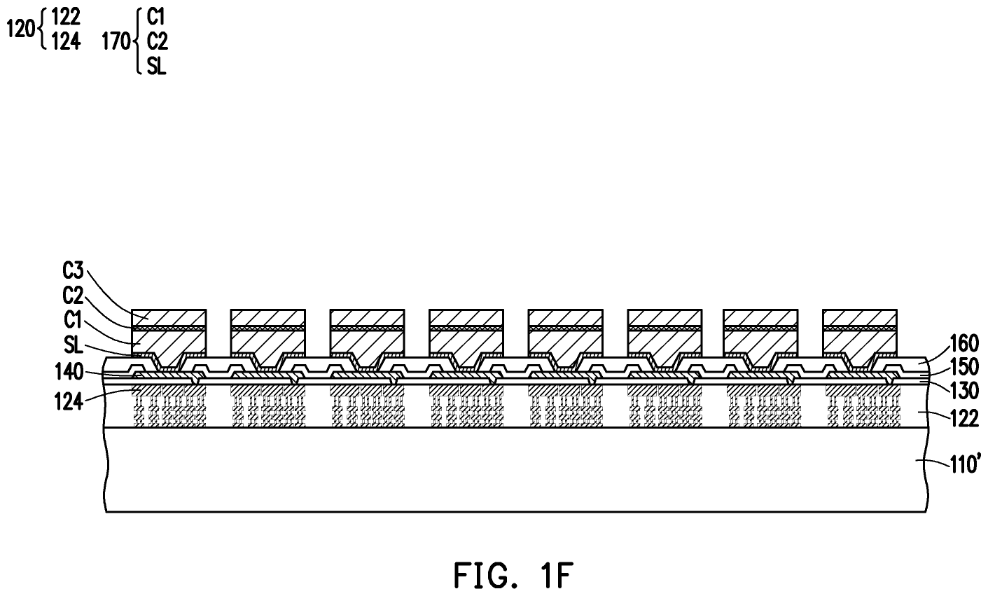

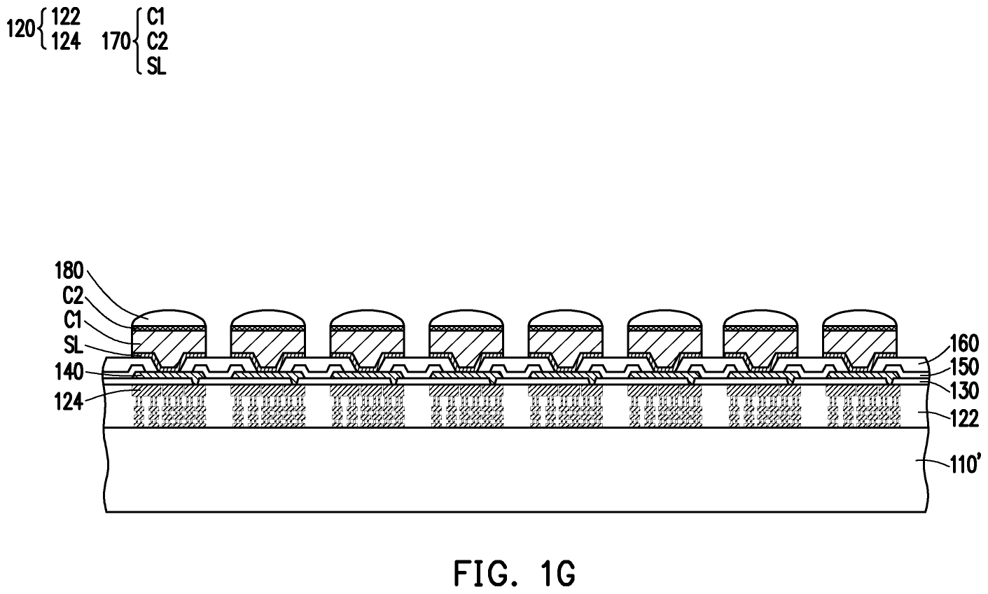

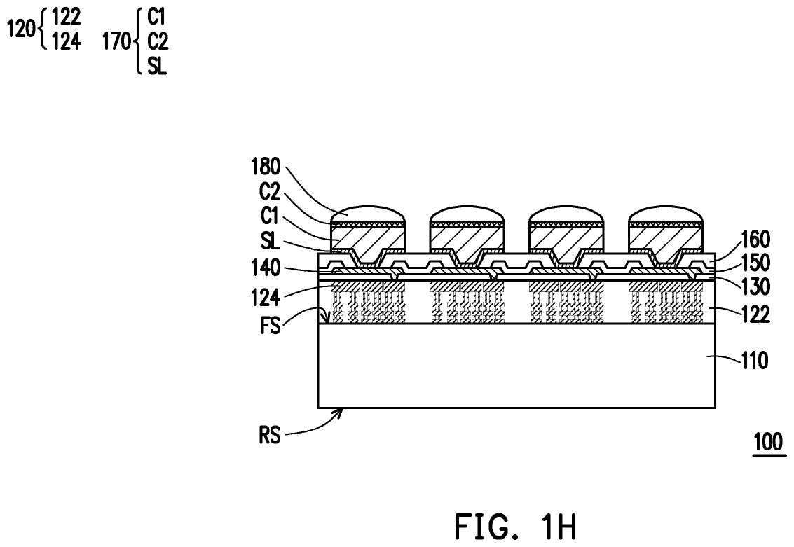

FIG. 1A to FIG. 1H are schematic cross-sectional views illustrating a manufacturing process of a semiconductor die 100 in accordance with some embodiments of the disclosure. Referring to FIG. 1A, a semiconductor wafer 110′ is provided. In some embodiments, the semiconductor wafer 110′ is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor wafer 110′ has active components (e.g., transistors or the like) and passive components (e.g., resistors, capacitors, inductors, or the like) formed therein.

In some embodiments, an interconnection structure 120 is formed on the semiconductor wafer 110′. In some embodiments, the interconnection structure 120 includes an inter-dielectric layer 122 and a plurality of patterned conductive layers 124. For simplicity, the inter-dielectric layer 122 is illustrated as a bulky layer in FIG. 1A, but it should be understood that the inter-dielectric layer 122 may be constituted by multiple dielectric layers. The patterned conductive layers 124 and the dielectric layers of the inter-dielectric layer 122 are stacked alternately. In some embodiments, two vertically adjacent patterned conductive layers 124 are electrically connected to each other through conductive vias sandwiched therebetween.

In some embodiments, a material of the inter-dielectric layer 122 includes polyimide, epoxy resin, acrylic resin, phenol resin, benzocyclobutene (BCB), polybenzoxazole (PBO), or other suitable polymer-based dielectric materials. The inter-dielectric layer 122 may be formed by suitable fabrication techniques, such as spin-on coating, chemical vapor deposition (CVD), plasma-enhanced chemical vapor deposition (PECVD), or the like. In some embodiments, a material of the patterned conductive layers 124 includes aluminum, titanium, copper, nickel, tungsten, and/or alloys thereof. The patterned conductive layers 124 may be formed by electroplating, deposition, and/or photolithography and etching. It should be noted that the number of the patterned conductive layers 124 and the dielectric layers in the inter-dielectric layer 122 shown in FIG. 1A is merely an exemplary illustration, and the disclosure is not limited. In some alternative embodiments, the number of the patterned conductive layers 124 and the dielectric layers in the inter-dielectric layer 122 may be adjusted depending on the routing requirements.

Referring to FIG. 1B, a dielectric layer 130 is formed over the interconnection structure 120. In some embodiments, a material of the dielectric layer 130 includes polyimide, epoxy resin, acrylic resin, phenol resin, BCB, PBO, or any other suitable polymer-based dielectric material. The dielectric layer 130 may be formed by suitable fabrication techniques, such as spin-on coating, CVD, PECVD, or the like. In some embodiments, a plurality of openings is formed in the dielectric layer 130 to expose portions of the topmost patterned conductive layer 124. After the openings are formed, a plurality of conductive pads 140 is formed over the dielectric layer 130. For example, the conductive pads 140 are formed over the semiconductor wafer 110′ and the interconnection structure 120 such that the interconnection structure 120 is located between the semiconductor wafer 110′ and the conductive pads 140. In some embodiments, the locations of the conductive pads 140 correspond to the locations of the openings of the dielectric layer 130. For example, the conductive pads 140 extend into the openings of the dielectric layer 130 to render electrical connection between the conductive pads 140 and portions of the interconnection structure 120 (i.e. the patterned conductive layer 124). In some embodiments, the conductive pads 140 are aluminum pads, copper pads, or other suitable metal pads. The number and the shape of the conductive pads 140 may be selected based on demand.

After the conductive pads 140 are distributed over the dielectric layer 130, a passivation layer 150 and a post-passivation layer 160 are sequentially formed over the dielectric layer 130 and the conductive pads 140. In some embodiments, the passivation layer 150 has a plurality of contact openings OP1 which partially exposes the conductive pads 140. In some embodiments, the passivation layer 150 is a silicon oxide layer, a silicon nitride layer, a silicon oxy-nitride layer, or a dielectric layer formed by other suitable dielectric materials. As illustrated in FIG. 1B, the post-passivation layer 160 covers the passivation layer 150 and has a plurality of contact openings OP2. The conductive pads 140 are partially exposed by the contact openings OP2 of the post-passivation layer 160. In some embodiments, the post-passivation layer 160 is a polyimide layer, a PBO layer, or a dielectric layer formed by other suitable polymers. It should be noted that the post-passivation layer 160 may be optional in some embodiments.

Referring to FIG. 1C, after forming the post-passivation layer 160, a seed layer SL is conformally formed on the post-passivation layer 160. For example, at least a portion of the seed layer SL extends into the contact openings OP2 of the passivation layer 160 to be in physical with the conductive pads 140. The seed layer SL may be formed through a sputtering process, a physical vapor deposition (PVD) process, or the like. In some embodiments, the seed layer SL is constituted by two sub-layers (not shown). The first sub-layer may include titanium, titanium nitride, tantalum, tantalum nitride, other suitable materials, or a combination thereof. On the other hand, the second sub-layer may include copper, copper alloys, or other suitable choice of materials.

Referring to FIG. 1D, a patterned photoresist layer PR is formed over the seed layer SL. In some embodiments, the patterned photoresist layer PR is made of a photosensitive material. In some embodiments, the patterned photoresist layer PR has a plurality of openings OP3 partially exposing the seed layer SL above the contact pads 140. For example, the openings OP3 expose the seed layer SL located directly above the contact pads 140.

Referring to FIG. 1E, a first conductive layer C1, a second conductive layer C2, and a third conductive layer C3 are sequentially deposited onto the exposed seed layer SL. For example, the first conductive layer C1, the second conductive layer C2, and the third conductive layer C3 are filled into the openings OP3 of the patterned photoresist layer PR. In some embodiments, the first conductive layer C1, the second conductive layer C2, and the third conductive layer C3 are formed through the same technique. However, the disclosure is not limited thereto. In some alternative embodiments, the first conductive layer C1, the second conductive layer C2, and the third conductive layer C3 may be formed by different techniques. In some embodiments, the first conductive layer C1, the second conductive layer C2, and the third conductive layer C3 are formed through a plating process. The plating process is, for example, an electro-plating process, an electroless-plating process, an immersion plating process, or the like. In some embodiments, materials of the first conductive layer C1, the second conductive layer C2, and the third conductive layer C3 are different. For example, the first conductive layer C1 is made of aluminum, titanium, copper, tungsten, and/or alloys thereof. On the other hand, the second conductive layer C2 is made of nickel. Moreover, the third conductive layer C3 is made of solder. In some embodiments, a thickness of the first conductive layer C1 is greater than a thickness of the second conductive layer C2 and a thickness of the third conductive layer C3. On the other hand, the thickness of third conductive layer C3 is greater than the thickness of the second conductive layer C2.

Referring to FIG. 1E and FIG. 1F, the patterned photoresist layer PR is removed. The patterned photoresist layer PR may be removed through an etching process, a stripping process, an ashing process, a combination thereof, or the like. Thereafter, by using the first conductive layer C1, the second conductive layer C2, and the third conductive layer C3 as hard masks, the seed layer SL that is uncovered by the first conductive layer C1, the second conductive layer C2, and the third conductive layer C3 is removed. In some embodiments, portions of the seed layer SL are removed through an etching process. After removal of portions of the seed layer SL, the remaining seed layer SL is located directly underneath the first conductive layer C1. That is, the seed layer SL is sandwiched between the contact pads 140 and the first conductive layer C1. In some embodiments, the remaining seed layer SL, the first conductive layer C1, and the second conductive layer C2 are collectively referred to as conductive posts 170.

Referring to FIG. 1F and FIG. 1G, a reflow process is performed on the third conductive layer C3 to transform the third conducive layer C3 into conductive terminals 180. That is, the conductive terminals 180 are formed on the conductive posts 170. In some embodiments, the third conductive layer C3 is reshaped during the reflow process to form hemispherical conductive terminals 180.

Referring to FIG. 1G and FIG. 1H, the structure illustrated in FIG. 1G is singulated to render a plurality of semiconductor dies 100 shown in FIG. 1H. In some embodiments, the singulation process typically involves dicing with a rotation blade and/or a laser beam. In other words, the singulation process includes a laser cutting process, a mechanical cutting process, a laser grooving process, other suitable processes, or a combination thereof. For example, a laser grooving process may be performed on the structure illustrated in FIG. 1G to form trenches (not shown) in the said structure. Thereafter, a mechanical cutting process may be performed on the locations of the trenches to cut through the said structure, so as to divide the semiconductor wafer 110′ into semiconductor substrates 110 and to obtain the semiconductor die 100.

As illustrated in FIG. 1H, the semiconductor die 100 includes the semiconductor substrate 110, the interconnection structure 120, the dielectric layer 130, the conductive pads 140, the passivation layer 150, the post-passivation layer 160, the conductive posts 170, and the conductive terminals 180. In some embodiments, the semiconductor substrate 110 has a front surface FS and a rear surface RS opposite to the front surface FS. The interconnection structure 120 is disposed on the front surface FS of the semiconductor substrate 110. The dielectric layer 130, the conductive pads 140, the passivation layer 150, and the post-passivation layer 160 are sequentially disposed over the interconnection structure 120. The conductive posts 170 are disposed over the post-passivation layer 160 and are electrically connected to the conductive pads 140. The conductive terminals 180 are disposed on the conductive posts 170.

In some embodiments, the semiconductor die 100 is capable of performing logic functions. For example, the semiconductor die 100 may be a Central Process Unit (CPU) die, a Graphic Process Unit (GPU) die, a Field-Programmable Gate Array (FPGA), or the like. In some embodiments, the semiconductor die 100 may be utilized in a package structure. For example, the semiconductor die 100 may be assembled with other components to form a package structure. The manufacturing process of the package structure utilizing the semiconductor die 100 will be described below.

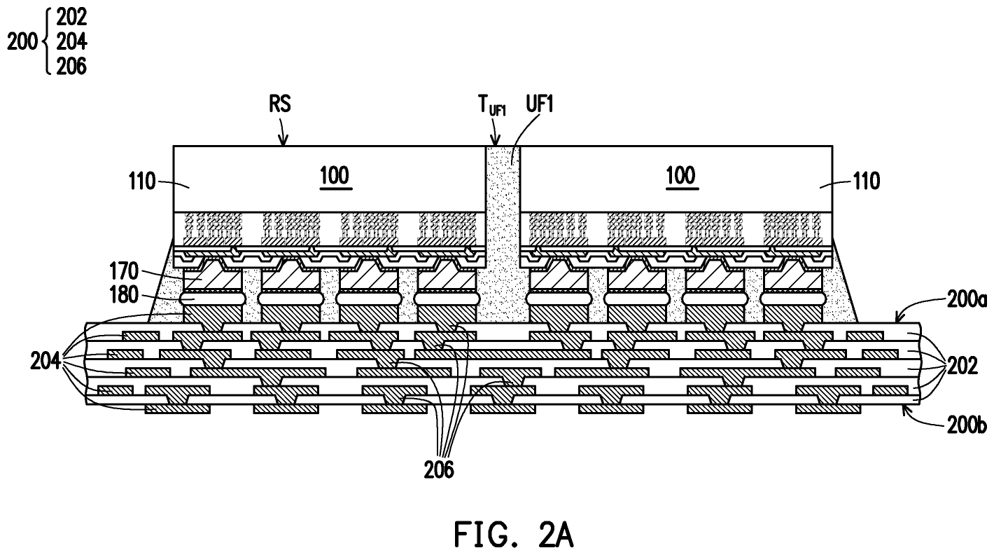

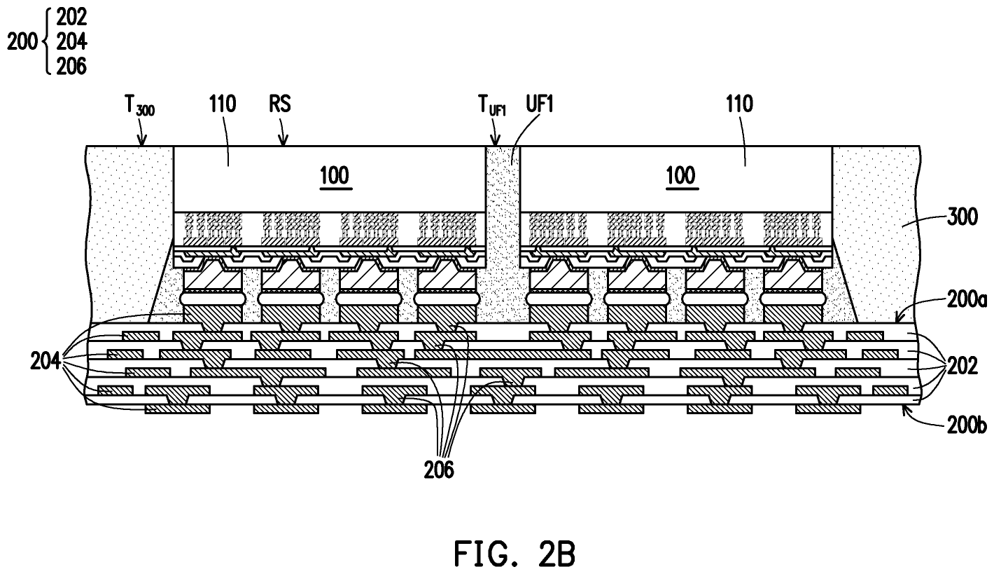

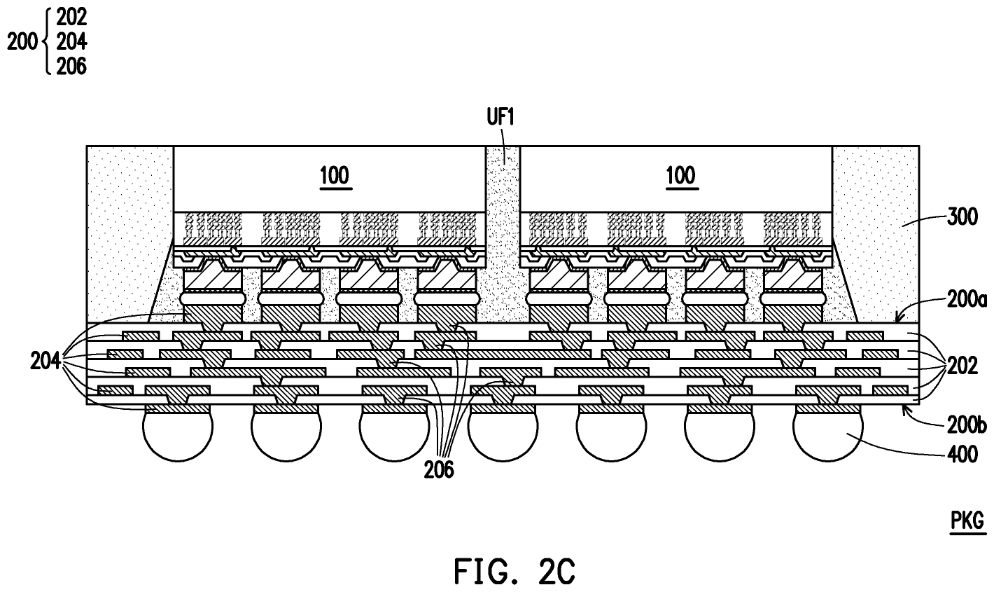

FIG. 2A to FIG. 2C are schematic cross-sectional views illustrating a manufacturing process of a package structure PKG in accordance with some embodiments of the disclosure. Referring to FIG. 2A, an interposer 200 is provided. In some embodiments, the interposer 200 includes a plurality of dielectric layers 202, a plurality of conductive pattern layers 204, and a plurality of conductive vias 206. In some embodiments, the dielectric layers 202 and the conductive pattern layers 204 are stacked alternately. On the other hand, the conductive vias 206 are embedded in the dielectric layers 202. In some embodiments, the conductive pattern layers 204 are interconnected with one another through the conductive vias 206. For example, the conductive vias 206 penetrate through the dielectric layers 202 to connect the conductive pattern layers 204. In some embodiments, each conductive pattern layer 204 includes a plurality of conductive patterns serving as redistribution wirings. In some embodiments, the conductive patterns of the outermost conductive pattern layers 204 (i.e. the topmost conductive pattern layer 204 and the bottommost conductive pattern layer 204 shown in FIG. 2A) are referred to as under-ball metallurgy (UBM) patterns for ball mount. In some embodiments, the conductive pattern layers 204 transmit signals horizontally and the conductive vias 206 transmit signals vertically.

In some embodiments, a material of the dielectric layers 202 includes polyimide, epoxy resin, acrylic resin, phenolic resin, BCB, PBO, or any other suitable polymer-based dielectric material. In some embodiments, the dielectric layers 202 include resin mixed with filler. The dielectric layers 202 may be formed by suitable fabrication techniques, such as film lamination, spin-on coating, CVD, PECVD, or the like. In some embodiments, a material of the conductive pattern layers 204 and the conductive vias 206 includes aluminum, titanium, copper, nickel, tungsten, or alloys thereof. The conductive pattern layers 204 and the conductive vias 206 may be formed by electroplating, deposition, and/or photolithography and etching. In some embodiments, the conductive pattern layers 204 and the underlying conductive vias 206 are formed simultaneously. It should be noted that the number of the dielectric layers 202, the number of the conductive pattern layers 204, and the number of the conductive vias 206 illustrated in FIG. 2A are merely for illustrative purposes, and the disclosure is not limited thereto. In some alternative embodiments, fewer or more layers of the dielectric layers 202, the conductive pattern layers 204, and the conductive vias 206 may be formed depending on the circuit design.

In some embodiments, the interposer 200 has a first surface 200a and a second surface 200b opposite to the first surface 200a. The topmost conductive pattern layer 204 is exposed at the first surface 200a and the bottommost conductive pattern layer 204 is exposed at the second surface 200b. As illustrated in FIG. 2A, the interposer 200 is a redistribution layer (RDL) interposer. However, the disclosure is not limited thereto. In some alternative embodiments, other types of interposers, such as silicon interpose, organic interposer, or the like, may be utilized as the interposer 200.

As illustrated in FIG. 2A, a plurality of semiconductor dies 100 in FIG. 1H is bonded to the first surface 200a of the interposer 200. In some embodiments, the semiconductor dies 100 are attached to the interposer 200 through the conductive terminals 180. For example, the conductive terminals 180 of the semiconductor dies 100 are in physical contact with the topmost conductive pattern layer 204 exposed at the first surface 200a of the interposer 200 to render electrical connection between the semiconductor dies 100 and the interposer 200. In some embodiments, after the conductive terminals 180 are attached to the topmost conductive pattern layer 204 of the interposer 200, a reflow process is performed to reshape the conductive terminals 180.

In some embodiments, the semiconductor dies 100 are attached to the interposer 200 through flip-chip bonding. In other words, the semiconductor dies 100 are placed such that the rear surfaces RS of the semiconductor substrates 110 face upward. As shown in FIG. 2A, two semiconductor dies 100 are bonded to the interposer 200. However, it should be noted that the number of the semiconductor dies 100 shown in FIG. 2A is merely an exemplary illustration, and the disclosure is not limited. In some alternative embodiments, the number of the semiconductor dies 100 may be adjusted depending on the design. For example, one single semiconductor die 100 may be bonded to the interposer 200 or more than two semiconductor dies 100 may be bonded to the interposer 200. Furthermore, as shown in FIG. 2A, two identical semiconductor dies 100 are bonded to the interposer 200. However, the disclosure is not limited thereto. In some alternative embodiments, semiconductor dies with different functions may be bonded to the interposer 200. For example, as mentioned above, the semiconductor die 100 is capable of performing logic functions. Therefore, in some alternative embodiments, one of the semiconductor dies 100 may be replaced by another die that is capable of performing storage function. For example, one of the semiconductor dies 100 may be replaced by a Dynamic Random Access Memory (DRAM), a Resistive Random Access Memory (RRAM), a Static Random Access Memory (SRAM), a Magnetoresistive Random Access Memory (MRAM), a Ferroelectric Random Access Memory (FeRAM), or the like.

In some embodiments, an underfill layer UF1 is formed over the interposer 200 to partially encapsulate the semiconductor dies 100. For example, the underfill layer UF1 wraps around the conductive posts 170 and the conductive terminals 180 of the semiconductor dies 100. The underfill layer UF1 also completely covers an inner sidewall of each semiconductor die 100 and partially covers outer sidewalls of each semiconductor die 100. For example, the portion of the underfill layer UF1 located between two adjacent semiconductor dies 100 has a top surface T_{UF1} that is substantially coplanar with the rear surfaces RS of the semiconductor substrates 110 of the semiconductor dies 100. However, the disclosure is not limited thereto. In some alternative embodiments, the top surface T_{UF1} of the underfill layer UF1 may be located below or above the rear surfaces RS of the semiconductor substrates 110. In some embodiments, a material of the underfill layer UF1 is an insulating material and includes a resin (e.g., epoxy resin), a filler material, a stress release agent (SRA), an adhesion promoter, other material, or a combination thereof. In some embodiments, the underfill layer UF1 is optional.

Referring to FIG. 2B, an encapsulant 300 is formed over the interposer 200 to encapsulate the semiconductor dies 100 and the underfill layer UF1. For example, the encapsulant 300 laterally encapsulates the semiconductor dies 100 and the underfill layer UF1. As illustrated in FIG. 2B, a top surface T₃₀₀ of the encapsulant 300 is substantially coplanar with the rear surfaces RS of the semiconductor substrates 110 of the semiconductor dies 100 and the top surface T_{UF1} of the underfill layer UF1. That is, the encapsulant 300 exposes the semiconductor substrates 110 of the semiconductor dies 100. In some embodiments, the encapsulant 300 is a molding compound, a molding underfill, a resin (such as epoxy), or the like. In some embodiments, the encapsulant 300 includes fillers. The fillers may be particles made of silica, aluminum dioxide, or the like. In some embodiments, the encapsulant 300 is formed by a molding process, an injection process, a combination thereof, or the like. The molding process includes, for example, a transfer molding process, a compression molding process, or the like.

Referring to FIG. 2C, a plurality of conductive terminals 400 is formed on the second surface 200b of the interposer 200. In some embodiments, the conductive terminals 400 are solder balls, ball grid array (BGA) balls, or the like. In some embodiments, the conductive terminals 400 are made of a conductive material with low resistivity, such as Sn, Pb, Ag, Cu, Ni, Bi, or an alloy thereof. In some embodiments, the conductive terminals 400 are in physical contact with the bottommost conductive pattern layer 204 exposed at the second surface 200b of the interposer 200.

After the conductive terminals 400 are formed, a singulation process is performed on the encapsulant 300 and the interposer 200 to obtain a plurality of package structures PKG. In some embodiments, the singulation process typically involves dicing with a rotation blade and/or a laser beam. In other words, the singulation process includes a laser cutting process, a mechanical cutting process, a laser grooving process, other suitable processes, or a combination thereof. In some embodiments, since the interposer 200 is in wafer form, the package structure PKG is considered to be formed by a chip-on-wafer process.

In some embodiments, the package structure PKG may be referred to as a “first device.” In some embodiments, the package structure PKG may be utilized in a semiconductor device. For example, the package structure PKG may be assembled with other components to form a semiconductor device. The manufacturing process of the semiconductor device utilizing the package structure PKG will be described below.

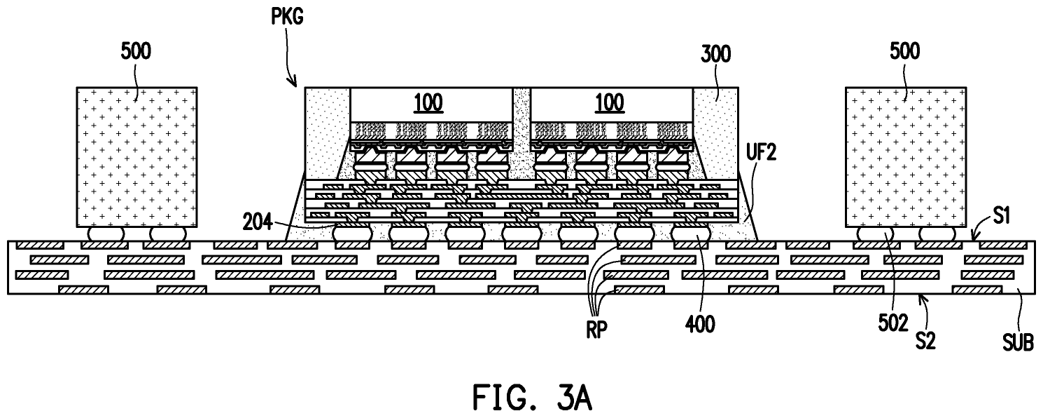

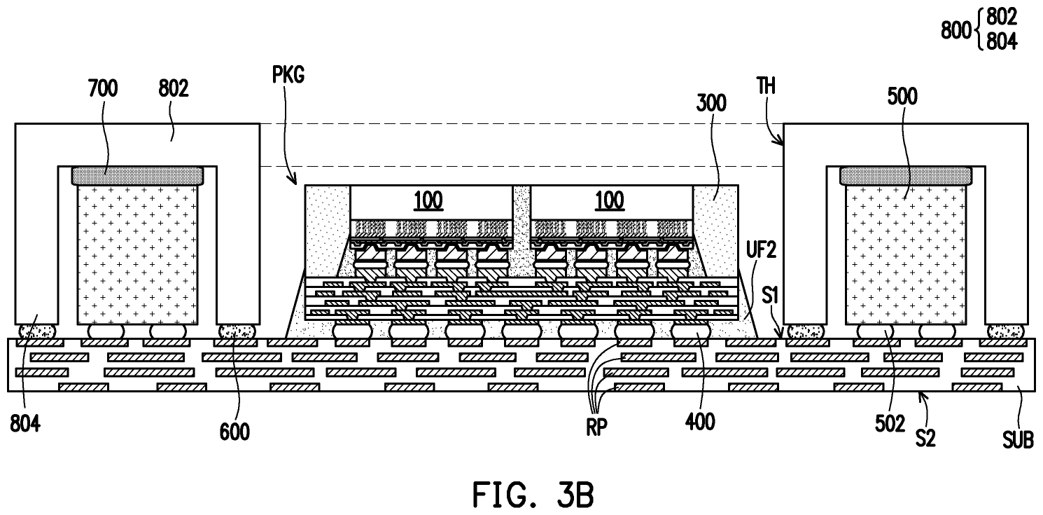

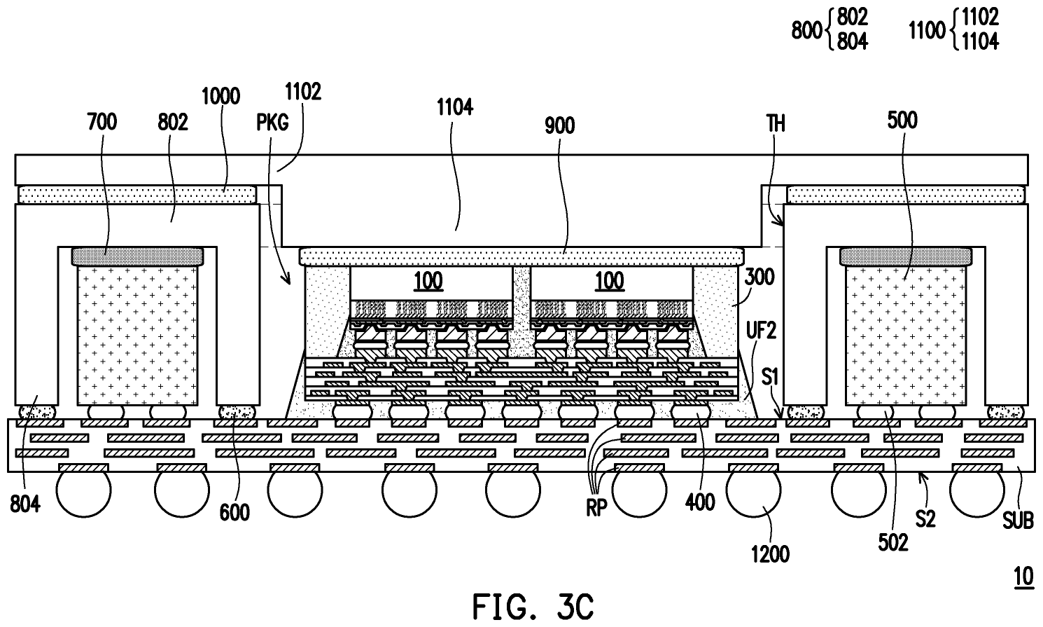

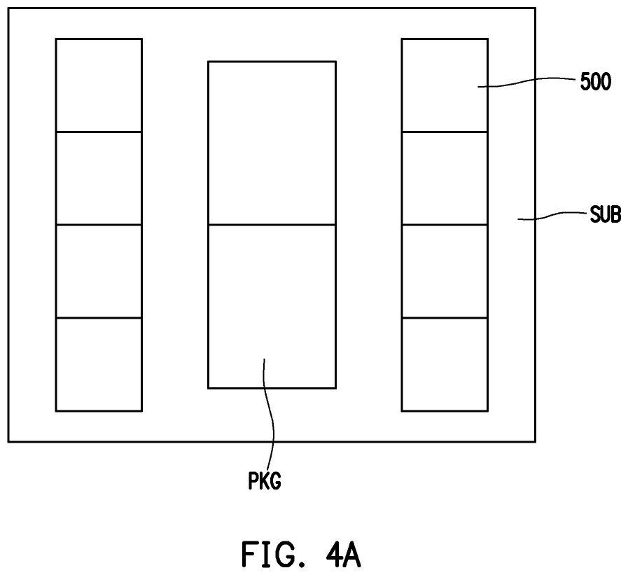

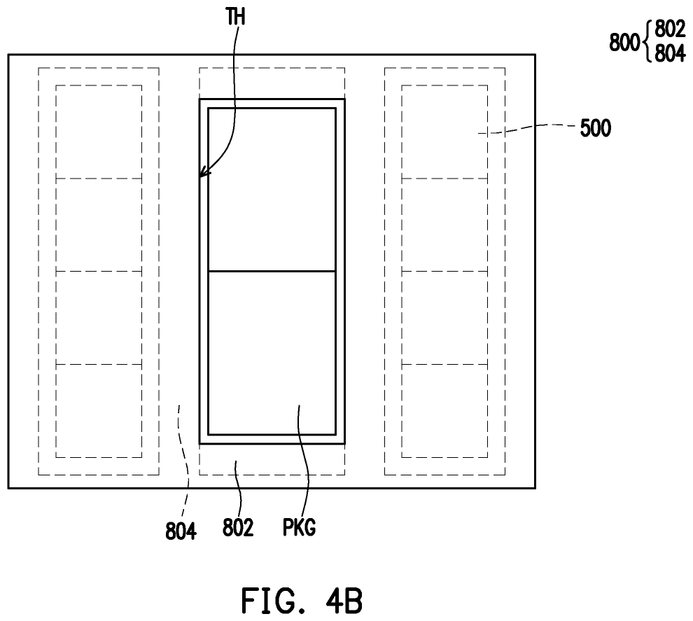

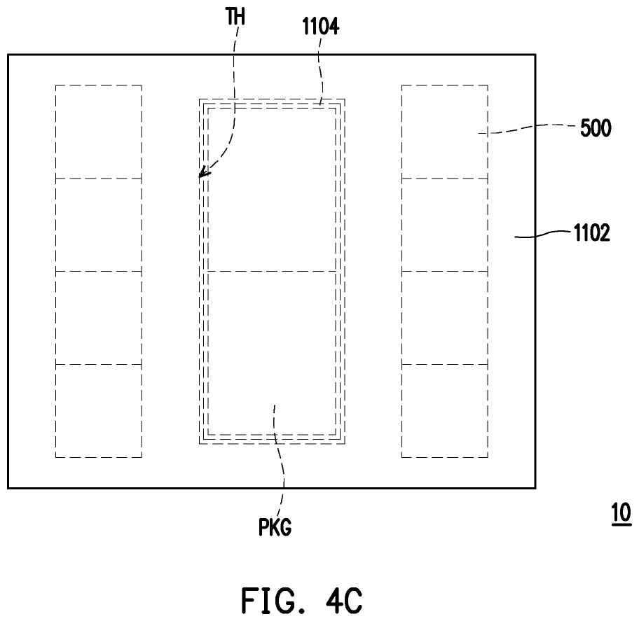

FIG. 3A to FIG. 3C are schematic cross-sectional views illustrating a manufacturing process of a semiconductor device 10 in accordance with some embodiments of the disclosure. FIG. 4A to FIG. 4C are schematic top views of FIG. 3A to FIG. 3C. Referring to FIG. 3A and FIG. 4A, a substrate SUB is provided. In some embodiments, the substrate SUB is a printed circuit board (PCB) or the like. In some embodiments, the substrate SUB is referred to as a circuit substrate. In some embodiments, the substrate SUB includes a plurality of routing patterns RP embedded therein. In some embodiments, the routing patterns RP are interconnected with one another. That is, the routing patterns RP are electrically connected to one another. As illustrated in FIG. 3A, the substrate SUB has a first surface S1 and a second surface S2 opposite to the first surface S1. In some embodiments, some of the routing patterns RP are exposed at the first surface S1 and some of the routing patterns RP are exposed at the second surface S2.

As illustrated in FIG. 3A and FIG. 4A, the package structure PKG in FIG. 2C is bonded to the first surface S1 of the substrate SUB. In some embodiments, the package structure PKG is attached to the substrate SUB through the conductive terminals 400. For example, the conductive terminals 400 of the package structure PKG are in physical contact with the routing patterns RP exposed at the first surface S1 of the substrate SUB to render electrical connection between the package structure PKG and the substrate SUB. In some embodiments, after the conductive terminals 400 are attached to the routing patterns RP of the substrate SUB, a reflow process may be performed to reshape the conductive terminals 400.

In some embodiments, an underfill layer UF2 is formed between the package structure PKG and the first surface S1 of the substrate SUB. For example, the underfill layer UF2 wraps around the bottommost conductive pattern layer 204 and the conductive terminals 400 of the package structure PKG. In some embodiments, the underfill layer UF2 is utilized to protect these elements. In some embodiments, the underfill layer UF2 further covers portions of each sidewall of the package structure PKG. In some embodiments, a material of the underfill layer UF2 is an insulating material and includes a resin (e.g., epoxy resin), a filler material, a stress release agent (SRA), an adhesion promoter, other material, or a combination thereof. In some embodiments, the underfill layer UF2 is optional. It should be noted that for simplicity, the underfill layer UF2 is omitted in FIG. 4A.

As shown in FIG. 4A, two package structures PKG are bonded to the substrate SUB. However, it should be noted that the number of the package structures PKG shown in FIG. 4A is merely an exemplary illustration, and the disclosure is not limited. In some alternative embodiments, the number of the package structures PKG may be adjusted depending on the design. For example, one single package structure PKG may be bonded to the substrate SUB or more than two package structures PKG may be bonded to the substrate SUB.

As illustrated in FIG. 3A and FIG. 4A, a plurality of memory device 500 is also bonded to the first surface S1 of the substrate SUB. In some embodiments, each memory device 500 is capable of performing storage functions. For example, the memory device 500 may be a DRAM, a RRAM, a SRAM, a MRAM, a FeRAM, or the like. In some embodiments, each memory device 500 includes a plurality of conductive connectors 502. In some embodiments, the conductive connectors 502 are solder balls, BGA balls, or the like. In some embodiments, the conductive connectors 502 are made of a conductive material with low resistivity, such as Sn, Pb, Ag, Cu, Ni, Bi, or an alloy thereof. In some embodiments, the memory device 500 may be referred to as a “second device.” As illustrated in FIG. 3A, the memory devices 500 are attached to the substrate SUB through the conductive connectors 502. For example, the conductive connectors 502 of the memory devices 500 are in physical contact with the routing patterns RP exposed at the first surface S1 of the substrate SUB to render electrical connection between the memory devices 500 and the substrate SUB. In some embodiments, after the conductive connectors 502 are attached to the routing patterns RP of the substrate SUB, a reflow process may be performed to reshape the conductive connectors 502.

As illustrated in FIG. 3A and FIG. 4A, the memory devices 500 are disposed adjacent to the package structures PKG. For example, the memory devices 500 may be disposed to surround the package structures PKG. As shown in FIG. 4A, eight memory devices 500 are bonded to the substrate SUB. However, it should be noted that the number of the memory devices 500 shown in FIG. 4A is merely an exemplary illustration, and the disclosure is not limited. In some alternative embodiments, the number of the memory devices 500 may be adjusted depending on the design.

Referring to FIG. 3B and FIG. 4B, an adhesive layer 600 is formed on the first surface S1 of the substrate SUB. For example, the adhesive layer 600 is formed to surround/encircle the package structures PKG and the memory devices 500. In some embodiments, the adhesive layer 600 partially covers the first surface S1 of the substrate SUB. For example, the package structures PKG, the underfill layer UF2, and the memory devices 500 are physically isolated from the adhesive layer 600. In some embodiments, the adhesive layer 600 is applied onto the substrate SUB through dispensing, spin-coating, or the like. In some embodiments, the adhesive layer 600 is a thermally conductive adhesive. For example, the adhesive layer 600 includes a silicone-based material, an epoxy-based material, a rubber-based material, or the like. In some embodiments, the adhesive layer 600 further includes a curing promoting agent therein to enhance curing. In some embodiments, the adhesive layer 600 has a thermal conductivity lower than about 0.5 W/m·K.

In some embodiments, an adhesive layer 700 is formed on the memory devices 500. In some embodiments, a material of the adhesive layer 700 is different from the material of the adhesive layer 600. For example, the adhesive layer 700 has a lower adhering ability and a higher thermal conductivity than the adhesive layer 600. In some embodiments, the adhesive layer 700 includes thermal interface material (TIM). In certain embodiments, the adhesive layer 700 includes polymeric TIM. In some embodiments, the polymeric TIM is made of a polymer (such as acetal, acrylic, cellulose, acetate, polyethylene, polystyrene, vinyl, nylon, polyolefin, polyester, silicone, paraffin, the like or a combination thereof) with thermal conductive fillers (such as divinyl benzene crosslinked-polymers, aluminum oxide, beryllium oxide, zinc oxide, silicon dioxide, boron nitride, aluminum nitride, aluminum, copper, silver, indium, the like, or a combination thereof). Alternatively, the adhesive layer 700 may include film-based or sheet-based TIM such as a sheet with synthesized carbon nanotube (CNT) structure integrated therein, thermal conductive sheet with vertically orientated graphite fillers, or the like. In some embodiments, the adhesive layer 700 has a thermal conductivity ranging from about 0.5 W/(m·K) to about 10 W/(m·K).

As illustrated in FIG. 3B and FIG. 4B, a ring structure 800 is disposed over the substrate SUB and the memory device 500. In some embodiments, the ring structure 800 is formed from a material with high thermal conductivity, such as copper, aluminum, cobalt, stainless steel, tungsten, copper-tungsten, copper-molybdenum, aluminum nitride, aluminum silicon carbide, alloy 42, the like, or a combination thereof. In some embodiments, the ring structure 800 is partially coated with another metal, such as gold, nickel, titanium gold alloy, lead, tin, nickel vanadium, the like, or a combination thereof. In some embodiments, the ring structure 800 includes a cover 802 and a leg 804 extending out from the cover 802. As illustrated in FIG. 3B, the cover 802 and the leg 804 are integrally formed, and the leg 804 extends downward from the cover 802. In some embodiments, an extending direction of the cover 802 is perpendicular to an extending direction of the leg 804. For example, the cover 802 extends horizontally while the leg 804 extends vertically. In some embodiments, the cover 802 has a through opening TH penetrating through the cover 802. It should be noted that the dotted lines shown in FIG. 3B denote the contour of the cover 802 that is located at a plane behind the cross-sectional of FIG. 3B.

As illustrated in FIG. 3B and FIG. 4B, the ring structure 800 is attached to the substrate SUB and the memory devices 500. For example, the leg 804 of the ring structure 800 is attached to the substrate SUB through the adhesive layer 600, and the cover 802 of the ring structure 800 is attached to the memory devices 500 through the adhesive layer 700. That is, the adhesive layer 600 is disposed between the leg 804 of the ring structure 800 and the substrate SUB, and the adhesive layer 700 is disposed between the cover 802 of the ring structure 800 and the memory devices 500. As illustrated in FIG. 3B and FIG. 4B, the leg 804 of the ring structure 800 surrounds the package structures PKG and the memory devices 500. On the other hand, the cover 802 of the ring structure 800 covers the memory devices 500 from the top view in FIG. 4B. Meanwhile, the through opening TH of the cover 802 exposes the package structures PKG. For example, a vertical projection of the through opening TH onto the substrate SUB is overlapped with a vertical projection of the package structures PKG onto the substrate SUB. In some embodiments, a size of the through opening TH of the cover 802 is larger than a total top surface area of the package structures PKG, so as to completely expose top surfaces of the package structures PKG. It should be noted that for simplicity, the underfill layer UF2 is omitted in FIG. 4B.

Referring to FIG. 3C and FIG. 4C, an adhesive layer 900 is formed on the top surfaces of the package structures PKG. In some embodiments, the adhesive layer 900 is applied onto the package structures PKG through dispensing, spin-coating, or the like. In some embodiments, a material of the adhesive layer 900 is different from the material of the adhesive layer 600 and the material of the adhesive layer 700. For example, the adhesive layer 900 includes phase change thermal interface material (PCTIM). Throughout the entire disclosure, PCTIM refers to a material that exhibits state change or phase change when subjected to a phase changing temperature (usually around 40° C. to 60° C.). For example, when subjected to the phase changing temperature, the PCTIM would change from a rigid state (for example, a solid state) to a softer state (for example, a liquid state). In some embodiments, the PCTIM is made of a matrix including a polymer component (such as a silicone-organic block copolymer), a thermally conductive filler, a treating agent, and an antioxidant. The silicone-organic block copolymer includes, for example, a silicone acrylate block copolymer, a silicone-amide block copolymer, a silicone-epoxy block copolymer, a silicone-ester block copolymer, a silicone-ether block copolymer, a silicone-imide block copolymer, a silicone-styrene block copolymer, a silicone-urethane block copolymer, a silicone-urea block copolymer, a silicone-vinylether block copolymer, or a combination thereof. The thermally conductive filler includes aluminum nitride, aluminum oxide, barium titanate, beryllium oxide, boron nitride, diamond, graphite, magnesium oxide, metal particulate, silicon carbide, tungsten carbide, zinc oxide, or a combination thereof. The treating agent includes alkoxysilane or the like. The antioxidant includes phenolic antioxidants and combinations of phenolic antioxidants with stabilizers. The stabilizers include organophosphorous derivatives such as trivalent organophosphorous compound, phosphites, phosphonates, and a combination thereof; thiosynergists such as organosulfur compounds including sulfides, dialkyldithiocarbamate, dithiodipropionates, and a combination thereof; and sterically hindered amines such as tetramethyl-piperidine derivatives. In certain embodiments, the PCTIM includes paraffin wax, alkyl hydrocarbons, amorphous ethylene propylene rubber, the like, or a combination thereof. In some embodiments, the PCTIM further includes thin metal pad alloy of tin, indium, and bismuth. In some embodiments, the PCTIM takes the form of a thin pad or an elastomer.

It should be noted that PCTIM is merely one kind of the materials of the adhesive layer 900, and the disclosure is not limited thereto. In some alternative embodiments, the adhesive layer 900 may be made of other materials, such as metallic TIM. In some embodiments, the metallic TIM is formed by purely metallic materials. For example, the metallic TIM is free of organic material and polymeric material. In some embodiments, the metallic TIM is made of a liquid state metal material, such as solder, tin, bismuth, lead, cadmium, zinc, gallium, indium, tellurium, mercury, thallium, antimony, selenium, polonium, rhodium, palladium, platinum, silver, gold, the like, or a combination thereof. In some embodiments, when the adhesive layer 900 is made of the metallic TIM, a first back side metallization layer (not shown) is formed between the package structures PKG and the adhesive layer 900 to strengthen the adhesion between these elements. In some embodiments, the first back side metallization layer is a composite layer constituted by Ti/Au, Ti/Cu/NiV/Au, Ti/Ni/Ag, Ti/Ni/Ti/Ag, Ti/Ni/Ag/Ni, Ti/Ni/Ag/Sn, or the like. In addition, a second back side metallization layer (not shown) is formed above the adhesive layer 900 to strength the adhesion between the adhesive layer 900 and the subsequently formed lid structure 1100. In some embodiments, the second back side metallization layer is a composite layer constituted by Ni/Au or the like.

In some embodiments, the adhesive layer 900 has a thermal conductivity about the same or higher than that of the adhesive layer 700. For example, the thermal conductivity of the adhesive layer 900 ranges from about 5 W/(m·K) to about 90 W/(m·K).

In some embodiments, an adhesive layer 1000 is formed on a top surface of the ring structure 800. For example, the adhesive layer 1000 is formed on a top surface of the cover 802. In some embodiments, the adhesive layer 1000 is applied onto the cover 802 of the ring structure 800 through dispensing, spin-coating, or the like. In some embodiments, a material of the adhesive layer 1000 is the same as the material of the adhesive layer 900. For example, the adhesive layer 1000 includes PCTIM.

As illustrated in FIG. 3C and FIG. 4C, a lid structure 1100 is provided. In some embodiments, the lid structure 1100 is disposed over the ring structure 800 and the package structures PKG. In some embodiments, a material of the lid structure 1100 is the same as the material of the ring structure 800. However, the disclosure is not limited thereto. In some alternative embodiments, the material of the lid structure 1100 is different from the material of the ring structure 800. For example, the material of the lid structure 1100 includes super conductive materials, such as silver diamond (AgD), diamond-like carbon (DLC), silver diamond composite, copper diamond composite, aluminum diamond composite, alloy 42 diamond composite, carbon metal composite, the like, or a combination thereof. In some embodiments, these super conductive materials have a thermal conductivity ranging from about 390 W/(m·K) to about 900 W/(m·K).

In some embodiments, the lid structure 1100 includes a body 1102 and a protrusion 1104 protruding from the body 1102. As illustrated in FIG. 3C, the body 1102 and the protrusion 1104 are integrally formed, and the protrusion 1104 extends downward from the body 1102. In some embodiments, an extending direction of the body 1102 is perpendicular to an extending direction of the protrusion 1104. For example, the body 1102 extends horizontally while the protrusion 1104 extends vertically.

As illustrated in FIG. 3C, the protrusion 1104 of the lid structure 1100 is inserted into the through opening TH of the cover 802 of the ring structure 800 such that the lid structure 1100 is attached to the ring structure 800 and the package structures PKG. For example, the protrusion 1104 of the lid structure 1100 is attached to the package structures PKG through the adhesive layer 900, and the body 1102 of the lid structure 1100 is attached to the cover 802 of the ring structure 800 through the adhesive layer 1000. That is, the adhesive layer 900 is disposed between the protrusion 1104 of the lid structure 1100 and the package structures PKG, and the adhesive layer 1000 is disposed between the body 1102 of the lid structure 1100 and cover 802 of the ring structure 800.

As illustrated in FIG. 3C and FIG. 4C, a shape of the protrusion 1104 of lid structure 1100 corresponds to a shape of the through opening TH of the cover 802 of the ring structure 800. However, a size of the protrusion 1104 is smaller than the size of the through opening TH, so when the protrusion 1104 is inserted into the through opening TH, sidewalls of the protrusion 1104 are spaced apart from sidewalls of the cover 802. That is, the lid structure 1100 is spatially separated from the ring structure 800.

As illustrated in FIG. 3C and FIG. 4C, the ring structure 800, the lid structure 1100, and the substrate SUB together encloses the package structures PKG and the memory devices 500. In other words, the memory devices 500 are disposed between the ring structure 800 and the substrate SUB while the package structures PKG are disposed between the lid structure 1100 and the substrate SUB. In some embodiments, the leg 804 of the ring structure 800 is spatially separated from the package structures PKG, the underfill layer UF2, and the memory devices 500. Meanwhile, the cover 802 of the ring structure 800 is spatially separated from the memory devices 500 and the body 1102 of the lid structure 1100. Moreover, the protrusion 1104 of the lid structure 1100 is spatially separated from the package structures PKG and the cover 802 of the ring structure 800.

After the lid structure 1100 is attached to the ring structure 800 and the package structures PKG, a plurality of conductive terminals 1200 is formed on the second surface S2 of the substrate SUB to obtain the semiconductor device 10. In some embodiments, the conductive terminals 1200 are solder balls, BGA balls, or the like. In some embodiments, the conductive terminals 1200 are made of a conductive material with low resistivity, such as Sn, Pb, Ag, Cu, Ni, Bi, or an alloy thereof. In some embodiments, the conductive terminals 1200 are in physical contact with the routing patterns RP exposed at the second surface S2 of the substrate SUB.

As mentioned above, the adhesive layer 900 and the adhesive layer 1000 include PCTIM that is able to change its state in response to the temperature of the environment. In some embodiments, during the manufacturing process of the semiconductor device 10 or during the operation of the semiconductor device 10, the semiconductor device 10 is subjected to various temperatures. Since the PCTIM is able to change its state depending on different temperatures, the PCTIM is able to provide a flexible bonding interface between components of the semiconductor device 10, so as to serve as an anti-stress mechanism when the semiconductor device 10 is subjected to different temperatures. In other words, the relative configurations of the ring structure 800, the lid structure 1100, the adhesive layer 900, and the adhesive layer 1000, together with the utilization of specific materials for these components, allow the semiconductor device 10 to have an excellent anti-stress ability, thereby avoiding issues such as warpage, delamination, or crack derived from stress generated due to change in temperature. Furthermore, since the ring structure 800, the lid structure 1100, the adhesive layer 900, and the adhesive layer 1000 all have excellent thermal conductivities, the thermal dissipation rate of the semiconductor device 10 may be sufficiently enhanced, and the reliability of the semiconductor device 10 may be ensured.

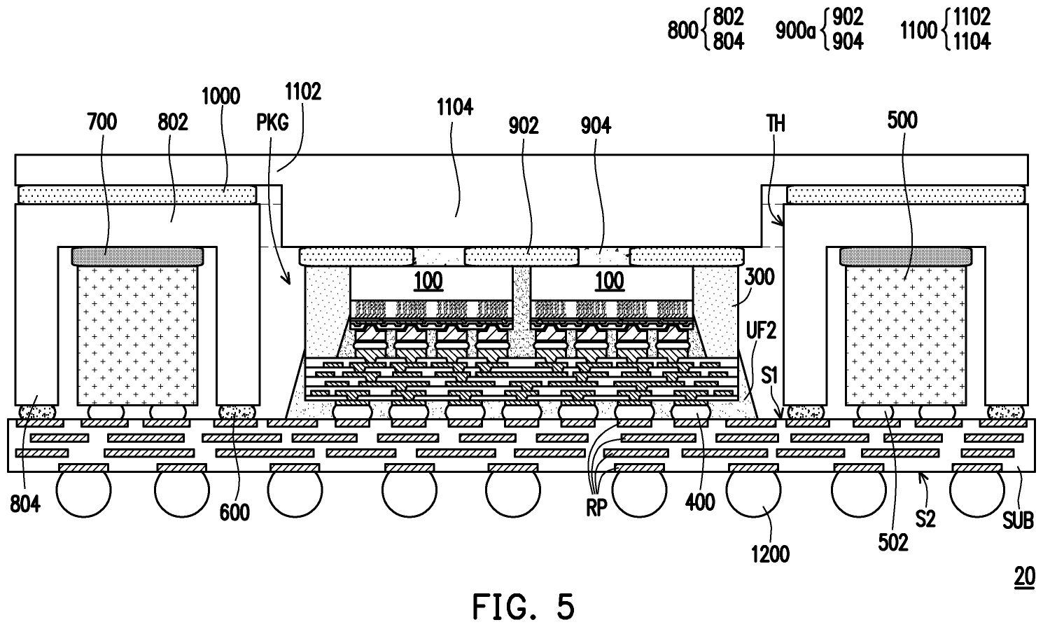

FIG. 5 is a schematic cross-sectional view illustrating a semiconductor device 20 in accordance with some alternative embodiments of the disclosure. Referring to FIG. 5, the semiconductor device 20 in FIG. 5 is similar to the semiconductor device 10 in FIG. 3C, so similar elements are denoted by the same reference numeral, and the detailed descriptions thereof are omitted herein. However, the adhesive layer 900 in FIG. 3C is replaced by the adhesive layer 900a in FIG. 5. In some embodiments, the adhesive layer 900a includes a first material layer 902 and a second material layer 904. In some embodiments, the second material layer 904 is adjacent to the first material layer 902. For example, as illustrated in FIG. 5, the second material layer 904 is sandwiched between the first material layer 902. In some embodiments, the first material layer 902 and the second material layer 904 respectively takes the form of strip-like, block-like, or island-like from a top view. In some embodiments, a material of the first material layer 902 is different from a material of the second material layer 904. For example, the first material layer 902 includes PCTIM while the second material layer 904 includes metallic TIM. In other words, the adhesive layer 900a may be referred to as a “composite adhesive layer.” The PCTIM and metallic TIM are being described above, so the detailed descriptions thereof are omitted herein.

As mentioned above, the adhesive layer 900a and the adhesive layer 1000 include PCTIM that is able to change its state in response to the temperature of the environment. In some embodiments, during the manufacturing process of the semiconductor device 20 or during the operation of the semiconductor device 20, the semiconductor device 20 is subjected to various temperatures. Since the PCTIM is able to change its state depending on different temperatures, the PCTIM is able to provide a flexible bonding interface between components of the semiconductor device 20, so as to serve as an anti-stress mechanism when the semiconductor device 20 is subjected to different temperatures. In other words, the relative configurations of the ring structure 800, the lid structure 1100, the adhesive layer 900a, and the adhesive layer 1000, together with the utilization of specific materials for these components, allow the semiconductor device 20 to have an excellent anti-stress ability, thereby avoiding issues such as warpage, delamination, or crack derived from stress generated due to change in temperature. Furthermore, since the ring structure 800, the lid structure 1100, the adhesive layer 900a, and the adhesive layer 1000 all have excellent thermal conductivities, the thermal dissipation rate of the semiconductor device 20 may be sufficiently enhanced, and the reliability of the semiconductor device 20 may be ensured.

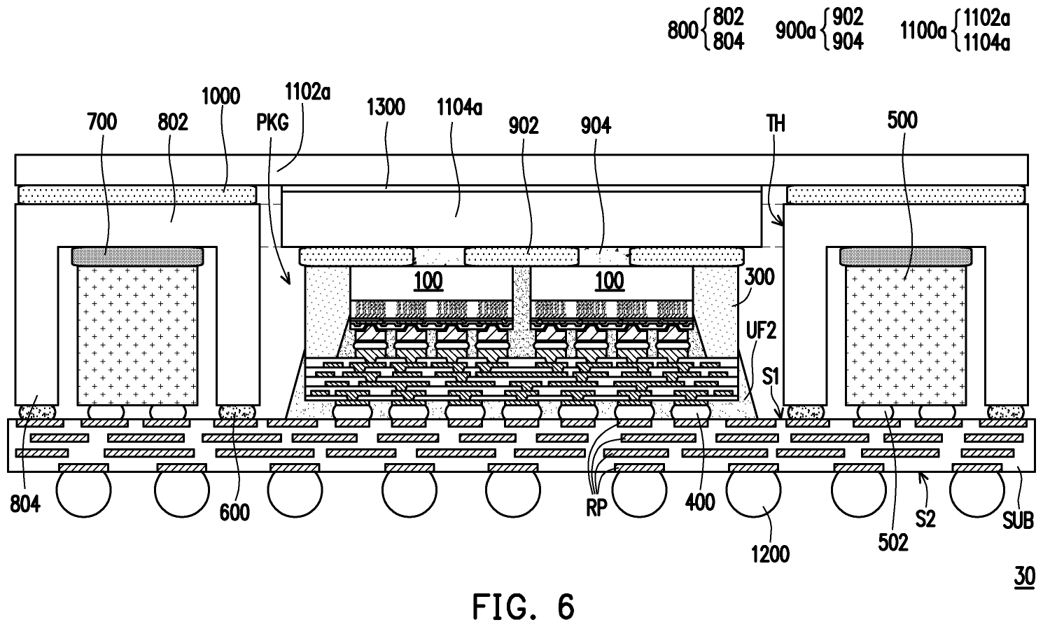

FIG. 6 is a schematic cross-sectional view illustrating a semiconductor device 30 in accordance with some alternative embodiments of the disclosure. Referring to FIG. 6, the semiconductor device 30 in FIG. 6 is similar to the semiconductor device 20 in FIG. 5, so similar elements are denoted by the same reference numeral, and the detailed descriptions thereof are omitted herein. However, the lid structure 1100 in FIG. 5 is replaced by the lid structure 1100a in FIG. 6. In some embodiments, the lid structure 1100a includes a body 1102a and a protrusion 1104a. In some embodiments, the body 1102a and the protrusion 1104a in FIG. 6 are respectively similar to the body 1102 and the protrusion 1104 in FIG. 3C and FIG. 5, so the detailed descriptions thereof are omitted herein. However, in the lid structure 1100a, the protrusion 1104a is spatially separated from the body 1102a. For example, the protrusion 1104a is attached to the body 1102a through a glue layer 1300. In some embodiments, the lid structure 1100a is per-formed before being attached to the ring structure 800 and the package structures PKG. For example, the protrusion 1104a is attached to the body 1102a prior to the attachment of the lid structure 1100a to the ring structure 800 and the package structures PKG.

In some embodiments, a material of the body 1102a and a material of the protrusion 1104a are the same. However, the disclosure is not limited thereto. In some alternative embodiments, the material of the body 1102a is different from the material of the protrusion 1104a. That is, the lid structure 1100a is made of at least two different materials. For example, the body 1102a is formed from a material with high thermal conductivity, such as copper, aluminum, cobalt, stainless steel, tungsten, copper-tungsten, copper-molybdenum, aluminum nitride, aluminum silicon carbide, alloy 42, the like, or a combination thereof. In some embodiments, the body 1102a is partially coated with another metal, such as gold, nickel, titanium gold alloy, lead, tin, nickel vanadium, the like, or a combination thereof. On the other hand, the protrusion 1104a includes super conductive materials, such as silver diamond (AgD), diamond-like carbon (DLC), silver diamond composite, copper diamond composite, aluminum diamond composite, alloy 42 diamond composite, carbon metal composite, the like, or a combination thereof.

As mentioned above, the adhesive layer 900a and the adhesive layer 1000 include PCTIM that is able to change its state in response to the temperature of the environment. In some embodiments, during the manufacturing process of the semiconductor device 30 or during the operation of the semiconductor device 30, the semiconductor device 30 is subjected to various temperatures. Since the PCTIM is able to change its state depending on different temperatures, the PCTIM is able to provide a flexible bonding interface between components of the semiconductor device 30, so as to serve as an anti-stress mechanism when the semiconductor device 30 is subjected to different temperatures. In other words, the relative configurations of the ring structure 800, the lid structure 1100a, the adhesive layer 900a, and the adhesive layer 1000, together with the utilization of specific materials for these components, allow the semiconductor device 30 to have an excellent anti-stress ability, thereby avoiding issues such as warpage, delamination, or crack derived from stress generated due to change in temperature. Furthermore, since the ring structure 800, the lid structure 1100a, the adhesive layer 900a, and the adhesive layer 1000 all have excellent thermal conductivities, the thermal dissipation rate of the semiconductor device 30 may be sufficiently enhanced, and the reliability of the semiconductor device 30 may be ensured.

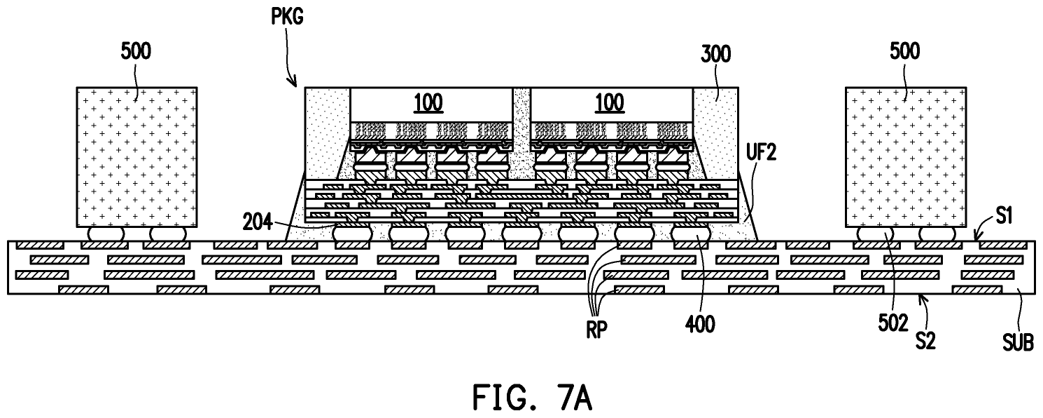

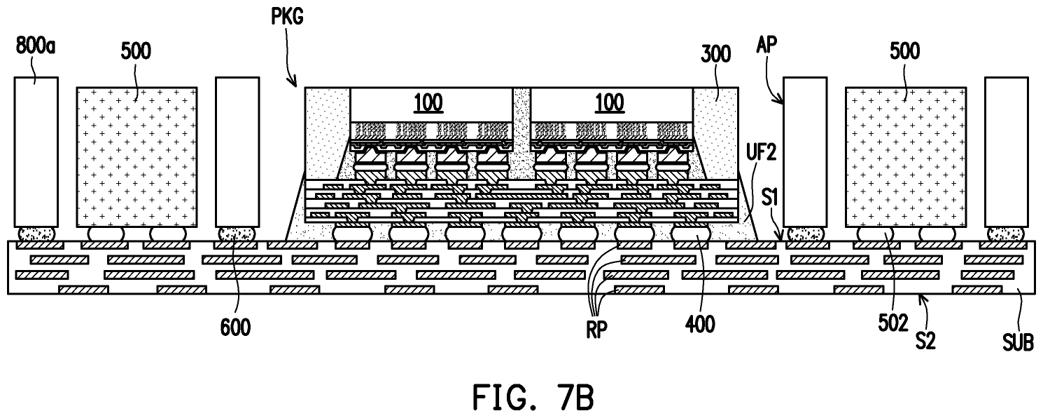

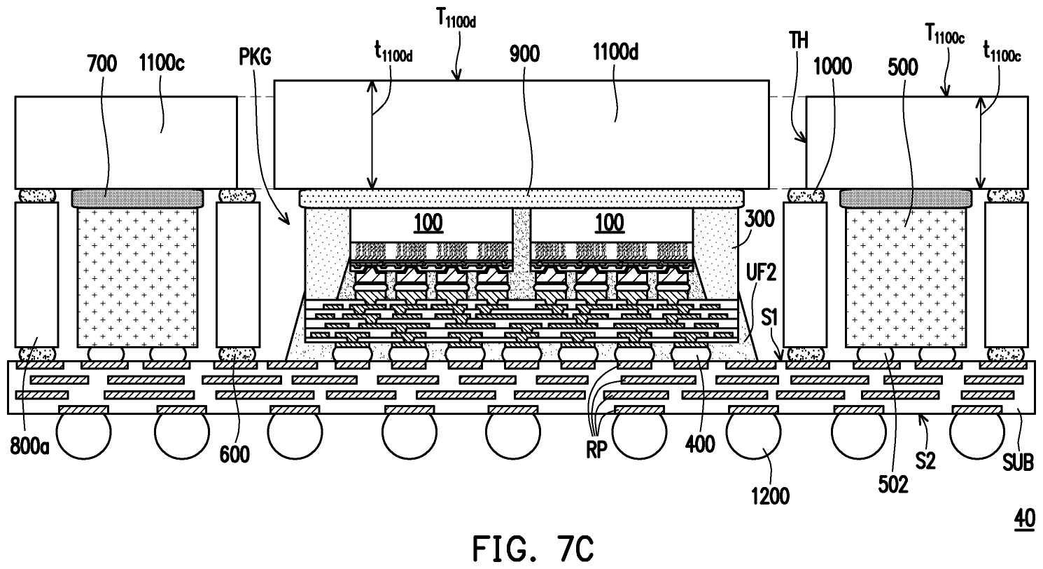

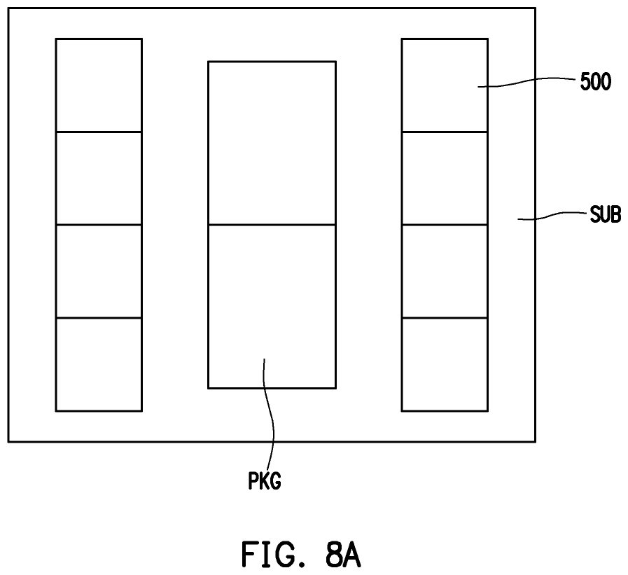

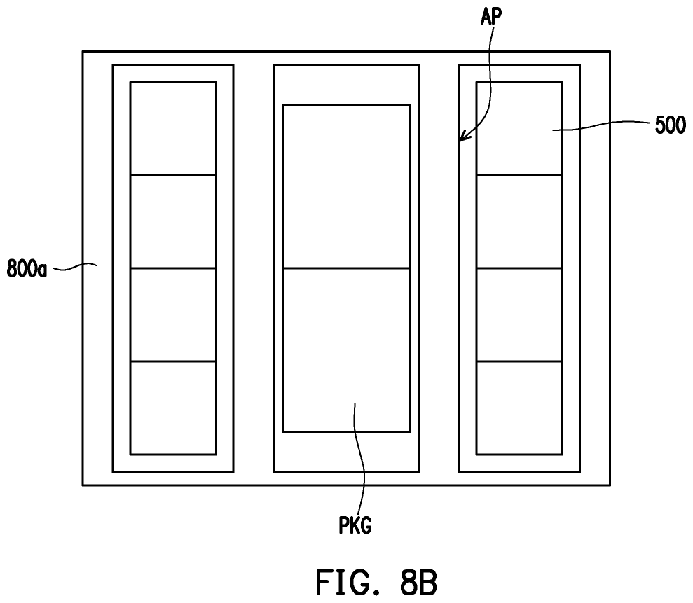

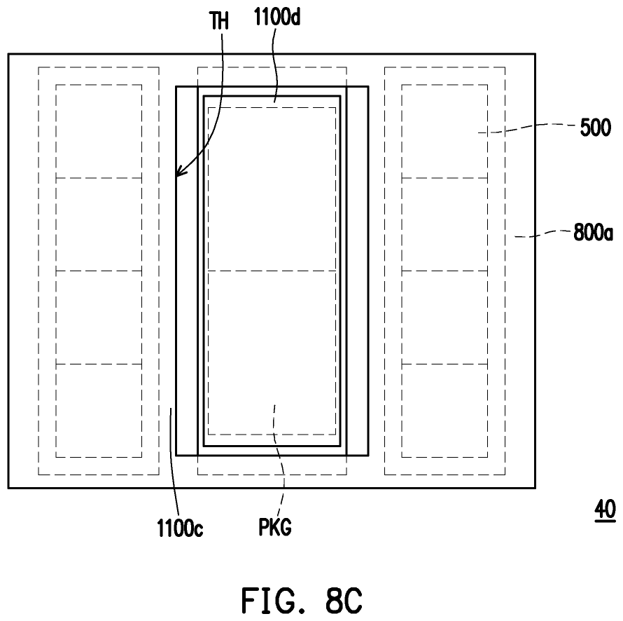

FIG. 7A to FIG. 7C are schematic cross-sectional views illustrating a manufacturing process of a semiconductor device 40 in accordance with some alternative embodiments of the disclosure. FIG. 8A to FIG. 8C are schematic top views of FIG. 7A to FIG. 7C. Referring to FIG. 7A and FIG. 8A, the step shown in FIG. 7A and FIG. 8A is similar to the step shown in FIG. 3A and FIG. 4A, so the detailed description thereof is omitted herein.

Referring to FIG. 7B and FIG. 8B, an adhesive layer 600 is formed on the first surface S1 of the substrate SUB. For example, the adhesive layer 600 is formed to surround/encircle the package structures PKG and the memory devices 500. In some embodiments, the adhesive layer 600 in FIG. 7B is similar to the adhesive layer 600 in FIG. 3B, so the detailed description thereof is omitted herein. It should be noted that for simplicity, the underfill layer UF2 is omitted in FIG. 8A.

As illustrated in FIG. 7B and FIG. 8B, a ring structure 800a is disposed over the substrate SUB. In some embodiments, the ring structure 800a is formed from a material with high thermal conductivity, such as copper, aluminum, cobalt, stainless steel, tungsten, copper-tungsten, copper-molybdenum, aluminum nitride, aluminum silicon carbide, alloy 42, the like, or a combination thereof. In some embodiments, the ring structure 800a is partially coated with another metal, such as gold, nickel, titanium gold alloy, lead, tin, nickel vanadium, the like, or a combination thereof. In some embodiments, the ring structure 800a is attached to the substrate SUB. For example, the ring structure 800a is attached to the substrate SUB through the adhesive layer 600. That is, the adhesive layer 600 is disposed between the ring structure 800a and the substrate SUB. As illustrated in FIG. 7B and FIG. 8B, the ring structure 800a surrounds the package structures PKG and the memory devices 500. For example, the ring structure 800a has apertures AP exposing the package structures PKG and the memory devices 500. That is, a vertical projection of the apertures AP onto the substrate SUB is overlapped with a vertical projection of the package structures PKG onto the substrate SUB and a vertical projection of the memory devices 500 onto the substrate SUB. In some embodiments, a total area of the apertures AP is larger than a total top surface area of the package structures PKG and the memory devices 500, so as to completely expose top surfaces of the package structures PKG and top surfaces of the memory devices 500. It should be noted that for simplicity, the underfill layer UF2 is omitted in FIG. 8B.

Referring to FIG. 7C and FIG. 8C, adhesive layer 700 is formed on the memory devices 500. In some embodiments, a material of the adhesive layer 700 is different from the material of the adhesive layer 600. In some embodiments, the adhesive layer 700 in FIG. 7C is similar to the adhesive layer 700 in FIG. 3B, so the detailed description thereof is omitted herein.

In some embodiments, an adhesive layer 900 is formed on the top surfaces of the package structures PKG. In some embodiments, a material of the adhesive layer 900 is different from the material of the adhesive layer 600 and the material of the adhesive layer 700. In some embodiments, the adhesive layer 900 in FIG. 7C is similar to the adhesive layer 900 in FIG. 3C, so the detailed description thereof is omitted herein. However, the disclosure is not limited thereto. In some alternative embodiments, the adhesive layer 900 in FIG. 7C may be similar to the adhesive layer 900a in FIG. 5. That is, the adhesive layer 900 in FIG. 7C includes PCTIM and/or metallic TIM. In some embodiments, an adhesive layer 1000 is formed on a top surface of the ring structure 800. In some embodiments, a shape and a material of the adhesive layer 1000 are respectively similar to the shape and the material of the adhesive layer 600, so the detailed descriptions thereof are omitted herein.

As illustrated in FIG. 7C and FIG. 8C, a first lid structure 1100c is disposed over the memory device 500 and the ring structure 800a. In some embodiments, the first lid structure 1100c is formed from a material with high thermal conductivity, such as copper, aluminum, cobalt, stainless steel, tungsten, copper-tungsten, copper-molybdenum, aluminum nitride, aluminum silicon carbide, alloy 42, the like, or a combination thereof. In some embodiments, the first lid structure 1100c is partially coated with another metal, such as gold, nickel, titanium gold alloy, lead, tin, nickel vanadium, the like, or a combination thereof. As illustrated in FIG. 7C and FIG. 8C, the first lid structure 1100c is attached to the memory devices 500 and the ring structure 800a. For example, the first lid structure 1100c is attached to the memory devices 500 through the adhesive layer 700. Meanwhile, the first lid structure 1100c is also attached to the ring structure 800a through the adhesive layer 1000. That is, the adhesive layer 700 is disposed between the first lid structure 1100c and the memory devices 500, and the adhesive layer 1000 is disposed between the first lid structure 1100c and the ring structure 800a. As illustrated in FIG. 7C and FIG. 8C, the first lid structure 1100c covers the memory devices 500 from the top view.

In some embodiments, the first lid structure 1100c has a through opening TH penetrating through the first lid structure 1100c. In some embodiments, the through opening TH of the first lid structure 1100c exposes the package structures PKG. For example, a vertical projection of the through opening TH onto the substrate SUB is overlapped with a vertical projection of the package structures PKG onto the substrate SUB. In some embodiments, a size of the through opening TH of the first lid structure 1100c is larger than a total top surface area of the package structures PKG, so as to completely expose top surfaces of the package structures PKG. In some embodiments, the through opening TH of the first lid structure 1100c also partially exposes the adhesive layer 1000 and the ring structure 800a. It should be noted that the dotted lines shown in FIG. 7C denote the contour of the first lid structure 1100c that is located at a plane behind the cross-sectional of FIG. 7C.

As illustrated in FIG. 7C and FIG. 8C, a second lid structure 1100d is disposed over the package structures PKG. In some embodiments, a material of the second lid structure 1100d is the same as the material of the first lid structure 1100c. However, the disclosure is not limited thereto. In some alternative embodiments, the material of the second lid structure 1100d is different from the material of the first lid structure 1100c. For example, the material of the second lid structure 1100d includes super conductive materials, such as silver diamond (AgD), diamond-like carbon (DLC), silver diamond composite, copper diamond composite, aluminum diamond composite, alloy 42 diamond composite, carbon metal composite, the like, or a combination thereof. In some embodiments, these super conductive materials have a thermal conductivity ranging from about 390 W/(m·K) to about 900 W/(m·K).

As illustrated in FIG. 7C, the second lid structure 1100d is placed in the through opening TH of the first lid structure 1100c such that the second lid structure 1100d is attached to the package structures PKG. In other words, the second lid structure 1100d is partially located in the through opening TH of the first lid structure 1100c. In some embodiments, the second lid structure 1100d is attached to the package structures PKG through the adhesive layer 900. That is, the adhesive layer 900 is disposed between the second lid structure 1100d and the package structures PKG.

In some embodiments, a thickness t 1100d of the second lid structure 1100d is greater than a thickness t_{1100c} of the first lid structure 1100c. In some embodiments, a top surface T_{1100c} of the first lid structure 1100c and a top surface T_{1100d} of the second lid structure 1100d are located at different level heights. For example, as illustrated in FIG. 7C, the top surface T_{1100c} of the first lid structure 1100c is located at a level height lower than that of the top surface T_{1100d} of the second lid structure 1100d.

As illustrated in FIG. 7C and FIG. 8C, a shape of the second lid structure 1100d corresponds to a shape of the through opening TH of the first lid structure 1100c. However, a size of the second lid structure 1100d is smaller than the size of the through opening TH, so when the second lid structure 1100d is placed in the through opening TH, sidewalls of the second lid structure 1100d are spaced apart from sidewalls of the first lid structure 1100c. That is, the second lid structure 1100d is spatially separated from the first lid structure 1100c.

As illustrated in FIG. 7C and FIG. 8C, the ring structure 800a, the first lid structure 1100c, and the substrate SUB together encloses the memory devices 500. In some embodiments, the memory devices 500 are disposed between the first lid structure 1100c and the substrate SUB while the package structures PKG are disposed between the second lid structure 1100d and the substrate SUB. In some embodiments, the ring structure 800a is spatially separated from the package structures PKG, the underfill layer UF2, and the memory devices 500. Meanwhile, the first lid structure 1100c is spatially separated from the memory devices 500 and the second lid structure 1100d. Moreover, the second lid structure 1100d is spatially separated from the package structures PKG.

After the first lid structure 1100c and the second lid structure 1100d are attached to the memory devices 500, the ring structure 800a, and the package structures PKG, a plurality of conductive terminals 1200 is formed on the second surface S2 of the substrate SUB to obtain the semiconductor device 40. In some embodiments, the conductive terminals 1200 are solder balls, BGA balls, or the like. In some embodiments, the conductive terminals 1200 are made of a conductive material with low resistivity, such as Sn, Pb, Ag, Cu, Ni, Bi, or an alloy thereof. In some embodiments, the conductive terminals 1200 are in physical contact with the routing patterns RP exposed at the second surface S2 of the substrate SUB.

As mentioned above, the adhesive layer 900 includes PCTIM that is able to change its state in response to the temperature of the environment. In some embodiments, during the manufacturing process of the semiconductor device 40 or during the operation of the semiconductor device 40, the semiconductor device 40 is subjected to various temperatures. Since the PCTIM is able to change its state depending on different temperatures, the PCTIM is able to provide a flexible bonding interface between components of the semiconductor device 40, so as to serve as an anti-stress mechanism when the semiconductor device 40 is subjected to different temperatures. In other words, the relative configurations of the ring structure 800a, the first lid structure 1100c, the second lid structure 1100d, and the adhesive layer 900, together with the utilization of specific materials for these components, allow the semiconductor device 40 to have an excellent anti-stress ability, thereby avoiding issues such as warpage, delamination, or crack derived from stress generated due to change in temperature. Furthermore, since the ring structure 800a, the first lid structure 1100c, the second lid structure 1100d, and the adhesive layer 900 all have excellent thermal conductivities, the thermal dissipation rate of the semiconductor device 40 may be sufficiently enhanced, and the reliability of the semiconductor device 40 may be ensured.

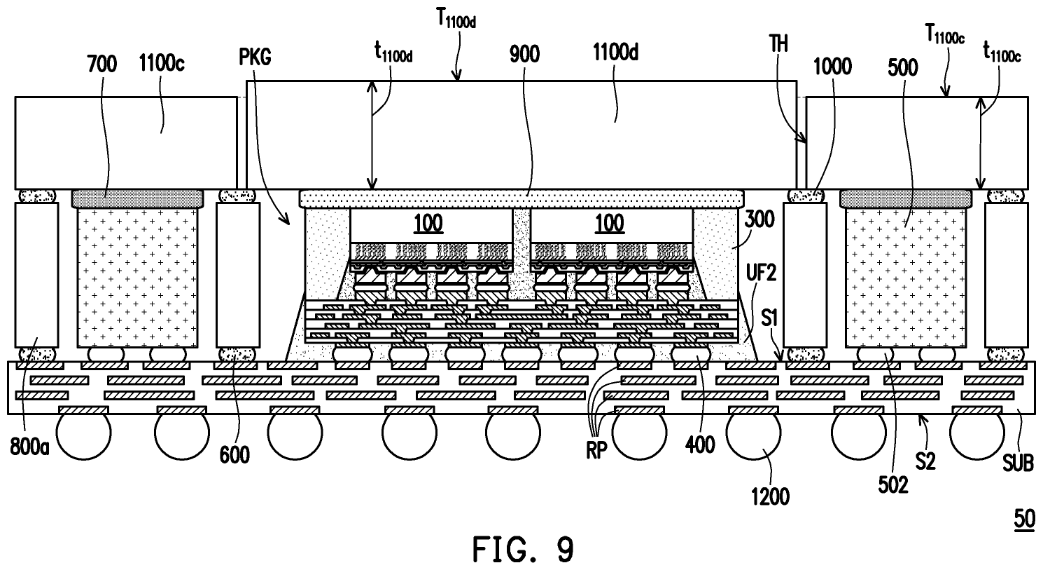

FIG. 9 is a schematic cross-sectional view illustrating a semiconductor device 50 in accordance with some alternative embodiments of the disclosure. Referring to FIG. 9, the semiconductor device 50 in FIG. 9 is similar to the semiconductor device 40 in FIG. 7C, so similar elements are denoted by the same reference numeral, and the detailed descriptions thereof are omitted herein. However, in the semiconductor device 50 in FIG. 9, the second lid structure 1100d extends over the ring structure 800a to partially cover the ring structure 800a. For example, the second lid structure 1100d is further attached to the ring structure 800a through the adhesive layer 1000. That is, the adhesive layer 1000 is disposed between the ring structure 800a and the second lid structure 1100d. In some embodiments, a size of the second lid structure 1100d is smaller than the size of the through opening TH of the first lid structure 1100c, so when the second lid structure 1100d is placed in the through opening TH, sidewalls of the second lid structure 1100d are spaced apart from sidewalls of the first lid structure 1100c. That is, the second lid structure 1100d is spatially separated from the first lid structure 1100c. As illustrated in FIG. 9, the ring structure 800a, the first lid structure 1100c, and the substrate SUB together encloses the memory devices 500. Meanwhile, the ring structure 800a, the second lid structure 1100d, and the substrate SUB together encloses the package structures PKG.

As mentioned above, the adhesive layer 900 includes PCTIM that is able to change its state in response to the temperature of the environment. In some embodiments, during the manufacturing process of the semiconductor device 50 or during the operation of the semiconductor device 50, the semiconductor device 50 is subjected to various temperatures. Since the PCTIM is able to change its state depending on different temperatures, the PCTIM is able to provide a flexible bonding interface between components of the semiconductor device 50, so as to serve as an anti-stress mechanism when the semiconductor device 50 is subjected to different temperatures. In other words, the relative configurations of the ring structure 800a, the first lid structure 1100c, the second lid structure 1100d, and the adhesive layer 900, together with the utilization of specific materials for these components, allow the semiconductor device 50 to have an excellent anti-stress ability, thereby avoiding issues such as warpage, delamination, or crack derived from stress generated due to change in temperature. Furthermore, since the ring structure 800a, the first lid structure 1100c, the second lid structure 1100d, and the adhesive layer 900 all have excellent thermal conductivities, the thermal dissipation rate of the semiconductor device 50 may be sufficiently enhanced, and the reliability of the semiconductor device 50 may be ensured.

In accordance with some embodiments of the disclosure, a semiconductor device includes a substrate, a first device, a second device, a ring structure, a lid structure, and a first adhesive layer. The first device is disposed on the substrate. The second device is adjacent to the first device and is disposed on the substrate. The ring structure is disposed over the substrate and the second device. The ring structure includes a cover and a leg extending out from the cover. The cover has a through opening. The lid structure is disposed over the ring structure and the first device. The lid structure includes a body and a protrusion protruding from the body. The protrusion of the lid structure is inserted into the through opening of the cover of the ring structure. The first adhesive layer is disposed between the lid structure and the cover of the ring structure. The first adhesive layer includes phase change thermal interface material (PCTIM).

In accordance with some alternative embodiments of the disclosure, a semiconductor device includes a substrate, a first device, a second device, a ring structure, a first lid structure, a second lid structure, and a first adhesive layer. The first device is disposed on the substrate. The second device is adjacent to the first device and is disposed on the substrate. The ring structure is disposed over the substrate to surround the first device and the second device. The first lid structure is disposed over the ring structure and the second device. The first lid structure has a through opening. The second lid structure is disposed over the first device. The second lid structure is partially located in the through opening of the first lid structure. A material of the second lid structure is different from a material of the first lid structure. The first adhesive layer is disposed between the second lid structure and the first device. The first adhesive layer includes phase change thermal interface material (PCTIM).

In accordance with some embodiments of the disclosure, a manufacturing method of a semiconductor device includes at least the following steps. A substrate is provided. A first device and a second device are bonded to the substrate. A ring structure is attached to the substrate and the second device. The ring structure includes a cover and a leg extending out from the cover. The cover has a through opening exposing the first device. A first adhesive layer is applied on the cover of the ring structure. A material of the first adhesive layer includes phase change thermal interface material (PCTIM). A lid structure is provided. The lid structure includes a body and a protrusion protruding from the body. The protrusion of the lid structure is inserted into the through opening of the cover of the ring structure, so as to attach the lid structure to the ring structure and the first device. The lid structure is attached to the ring structure through the first adhesive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first device disposed on the substrate;
a second device adjacent to the first device and disposed on the substrate;
a ring structure disposed over the substrate and the second device, wherein the ring structure comprises a cover and a leg extending out from the cover, and the cover has a through opening;
a lid structure disposed over the ring structure and the first device, wherein the lid structure comprises a body and a protrusion protruding from the body, and the protrusion of the lid structure is inserted into the through opening of the cover of the ring structure; and
a first adhesive layer disposed between the body of the lid structure and the cover of the ring structure, wherein the first adhesive layer comprises phase change thermal interface material (PCTIM).

2. The semiconductor device of claim 1, wherein a vertical projection of the through opening onto the substrate is overlapped with a vertical projection of the first device onto the substrate.

3. The semiconductor device of claim 1, further comprising:
a second adhesive layer disposed between the leg of the ring structure and the substrate;
a third adhesive layer disposed between the cover of the ring structure and the second device; and
a fourth adhesive layer disposed between the protrusion of the lid structure and the first device.

4. The semiconductor device of claim 3, wherein a material of the third adhesive layer is different from a material of the first adhesive layer.

5. The semiconductor device of claim 3, wherein the fourth adhesive layer comprises PCTIM.

6. The semiconductor device of claim 3, wherein the fourth adhesive layer comprises metallic TIM.

7. The semiconductor device of claim 3, wherein the fourth adhesive layer comprises a first material layer and a second material layer adjacent to the first material layer, the first material layer comprises PCTIM and the second material layer comprises metallic TIM.

8. The semiconductor device of claim 1, wherein the body and the protrusion of the lid structure are integrally formed.

9. The semiconductor device of claim 1, wherein the body and the protrusion of the lid structure are spatially separated, and the protrusion is attached to the body through a glue layer.

10. The semiconductor device of claim 9, wherein a material of the body is different from a material of the protrusion.

11. A semiconductor device, comprising:
a substrate;
a first device disposed on the substrate;
a second device adjacent to the first device and disposed on the substrate;
a ring structure disposed over the substrate to surround the first device and the second device;
a first lid structure disposed over the ring structure and the second device, wherein the first lid structure has a through opening;
a second lid structure disposed over the first device, wherein the second lid structure is partially located in the through opening of the first lid structure, and a material of the second lid structure is different from a material of the first lid structure; and
a first adhesive layer disposed between the second lid structure and the first device, wherein the first adhesive layer comprises phase change thermal interface material (PCTIM).

12. The semiconductor device of claim 11, wherein a top surface of the first lid structure and a top surface of the second lid structure are located at different level heights.

13. The semiconductor device of claim 11, wherein a thickness of the second lid structure is greater than a thickness of the first lid structure.

14. The semiconductor device of claim 11, further comprising:
a second adhesive layer disposed between the ring structure and the substrate;
a third adhesive layer disposed between the first lid structure and the second device; and
a fourth adhesive layer disposed between the first lid structure and the ring structure.

15. The semiconductor device of claim 14, wherein the fourth adhesive layer is further disposed between the ring structure and the second lid structure.

16. The semiconductor device of claim 14, wherein a material of the third adhesive layer is different from a material of the first adhesive layer.

17. The semiconductor device of claim 11, wherein the first adhesive layer further comprises metallic TIM.

18. A manufacturing method of a semiconductor device, comprising:
providing a substrate;
bonding a first device and a second device to the substrate;
attaching a ring structure to the substrate and the second device, wherein the ring structure comprises a cover and a leg extending out from the cover, and the cover has a through opening exposing the first device;
applying a first adhesive layer on the cover of the ring structure, wherein a material of the first adhesive layer comprises phase change thermal interface material (PCTIM);
providing a lid structure, wherein the lid structure comprises a body and a protrusion protruding from the body; and
inserting the protrusion of the lid structure into the through opening of the cover of the ring structure, so as to attach the lid structure to the ring structure and the first device, wherein the lid structure is attached to the ring structure through the first adhesive layer.

19. The method of claim 18, wherein the leg of the ring structure is attached to the substrate through a second adhesive layer, the cover of the ring structure is attached to the second device through a third adhesive layer, and the protrusion of the lid structure is attached to the first device through a fourth adhesive layer.

20. The method of claim 19, wherein a material of the fourth adhesive layer comprises PCTIM.
